(19) United States
(12) Patent Application Publication
(10) Pub. No.: US 2025/0224665 A1
(43) Pub. Date: Jul. 10, 2025

(54) METHOD OF EXTRACTING SUB-RESOLUTION ASSIST FEATURE (SRAF) PRINTING CONTOURS FROM SCANNING ELECTRON MICROSCOPE (SEM) IMAGE, OPTICAL PROXIMITY CORRECTION (OPC) METHOD, AND MASK MANUFACTURING METHOD INCLUDING THE OPC METHOD

(71) Applicant: SAMSUNG ELECTRONICS CO., LTD., Suwon-si (KR)

(72) Inventors: Mijin KWON, Suwon-si (KR); Mincheol KANG, Suwon-si (KR); Seunghune YANG, Suwon-si (KR)

(73) Assignee: SAMSUNG ELECTRONICS CO., LTD., Suwon-si (KR)

(21) Appl. No.: 18/794,683

(22) Filed: Aug. 5, 2024

(30) Foreign Application Priority Data
Jan. 5, 2024 (KR) 10-2024-0002306

(51) Int. Cl. G03F 1/36; G05B 19/4099

(52) U.S. Cl. CPC G03F 1/36; G05B 19/4099; G05B 2219/45031

(57) ABSTRACT

Provided are a method of extracting a sub-resolution assist feature (SRAF) contours, an optical proximity correction (OPC) method using the method of extracting SRAF contours, and a mask manufacturing method including the OPC method. The method of extracting the SRAF contours include obtaining a scanning electron microscope (SEM) image of a wafer through an SEM; identifying a main feature region and an SRAF printing region in the SEM image; extracting, from the SEM image, a main feature contour, which is an outermost line of the main feature region; extracting, from the SEM image, an SRAF printing contour, which is an outermost line of the SRAF printing region; and generating a final SEM contour image by merging the main feature contour with the SRAF printing contour.

### CROSS-REFERENCE TO RELATED APPLICATION

This application is based on and claims priority under 35 U.S.C. § 119 to Korean Patent Application No. 10-2024-0002306, filed on Jan. 5, 2024, in the Korean Intellectual Property Office, the disclosure of which is incorporated by reference herein in its entirety.

### BACKGROUND

One or more example embodiments of the disclosure relate to a method of extracting sub-resolution assist feature (SRAF) printing contours from a scanning electron microscope (SEM) image, an optical proximity correction (OPC) method using the same, and a mask manufacturing method including the OPC method.

In a semiconductor process, a photolithography process using a mask may be performed to form a pattern on a semiconductor substrate, such as a wafer. A mask may be simply defined as a pattern transfer material in which a pattern shape of an opaque material is formed on a transparent base material. To briefly describe a mask manufacturing process, first, a demanded circuit is designed, a layout for the circuit is designed, and then design data obtained through optical proximity correction (OPC) is transmitted as mask tape-out (MTO) design data. Afterwards, mask data preparation (MDP) may be performed based on the MTO design data, and a front end of line (FEOL) such as an exposure and a back end of line (BEOL) such as a defect inspection may be performed, thereby manufacturing a mask.

### SUMMARY

One or more example embodiments of the disclosure provide an optical proximity correction (OPC) method with improved prediction precision of sub-resolution assist feature (SRAF) printing and a mask manufacturing method including the OPC method.

In addition, the technical goals to be achieved by the disclosure are not limited to the technical goals mentioned above, and other technical goals may be clearly understood by one of ordinary skill in the art from the following descriptions.

According to an aspect of an example embodiment of the disclosure, there is provided a method of extracting an SRAF contour, the method including: obtaining a scanning electron microscope (SEM) image of a wafer through an SEM; identifying a main feature region and an SRAF printing region in the SEM image; extracting, from the SEM image, a main feature contour, which is an outermost line of the main feature region; extracting, from the SEM image, an SRAF printing contour, which is an outermost line of the SRAF printing region; and generating a final SEM contour image by merging the main feature contour with the SRAF printing contour.

According to aspect of an example embodiment of the disclosure, there is provided an OPC method including receiving a design layout for a target pattern; generating an OPC model for the design layout; and obtaining an OPC-ed design layout by performing a simulation using the OPC model, wherein the generating the OPC model includes obtaining an SEM image of a wafer through an SEM; identifying a main feature region and an SRAF printing region in the SEM image; extracting, from the SEM image, a main feature contour, which is an outermost line of the main feature region; extracting, from the SEM image, an SRAF printing contour, which is an outermost line of the SRAF printing region; generating a final SEM contour image by merging the main feature contour with the SRAF printing contour; generating a model gauge from the final SEM contour image; obtaining an SRAF prediction cost function using the model gauge; and using the SRAF prediction cost function as an input gauge for the OPC model.

According to aspect of an example embodiment of the disclosure, there is provided a method of manufacturing a mask, the method including receiving a design layout for a target pattern; generating an OPC model for the design layout; obtaining an OPC-ed design layout by performing a simulation using the OPC model; transmitting data regarding the OPC-ed design layout as mask tape-out (MTO) design data; preparing mask data based on the MTO design data; and performing exposure on a mask substrate based on the mask data, wherein the generating the OPC model includes obtaining an SEM image of a wafer through an SEM; identifying a main feature region and an SRAF printing region in the SEM image; extracting, from the SEM image, a main feature contour, which is an outermost line of the main feature region; extracting, from the SEM image, an SRAF printing contour, which is an outermost line of the SRAF printing region; generating a final SEM contour image by merging the main feature contour with the SRAF printing contour; generating a model gauge from the final SEM contour image; obtaining an SRAF prediction cost function using the model gauge; and using the SRAF prediction cost function as an input gauge for the OPC model, and wherein the model gauge includes information regarding whether at least one pattern in the final SEM contour image corresponds to an SRAF printing region and information regarding an area of the SRAF printing region corresponding to the at least one pattern.

### BRIEF DESCRIPTION OF THE DRAWINGS

Example embodiments of the disclosure will be more clearly understood from the following detailed description taken in conjunction with the accompanying drawings in which:

FIG. 1 is a schematic flowchart of a method of extracting sub-resolution assist feature (SRAF) contours according to an example embodiment;

FIGS. 2A to 2G are examples of scanning electron microscope (SEM) images for describing respective operations of FIG. 1;

FIG. 3 is a schematic flowchart of an optical proximity correction (OPC) method according to an example embodiment;

FIG. 4 is a flowchart schematically showing an operation of generating an OPC model of FIG. 3;

FIGS. 5A to 5C are examples of SEM images for describing SRAF printing prediction of FIG. 4; and

FIG. 6 is a schematic flowchart of operations of a mask manufacturing method including an OPC method, according to an example embodiment.

### DETAILED DESCRIPTION

Hereinafter, example embodiments of the disclosure will be described with reference to the accompanying drawings.

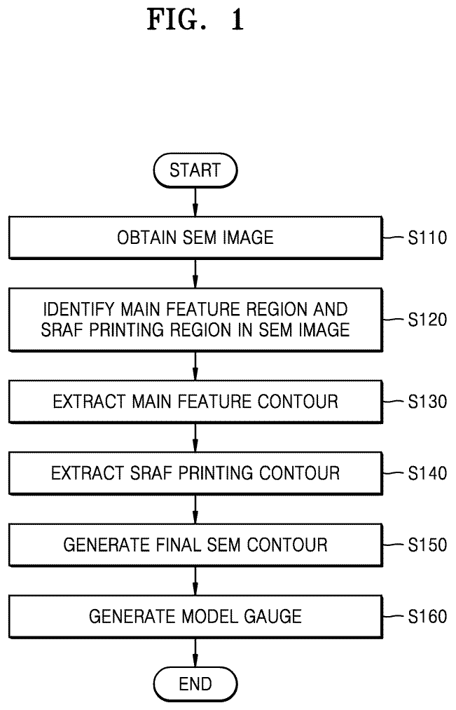

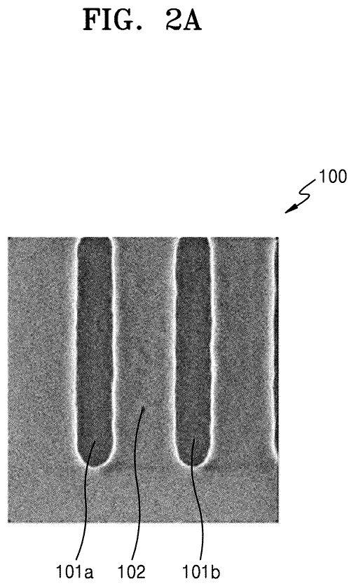

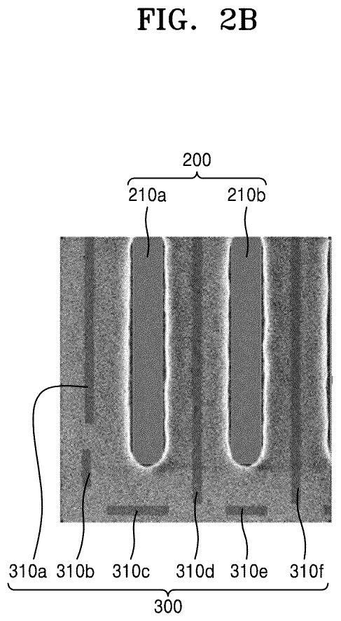

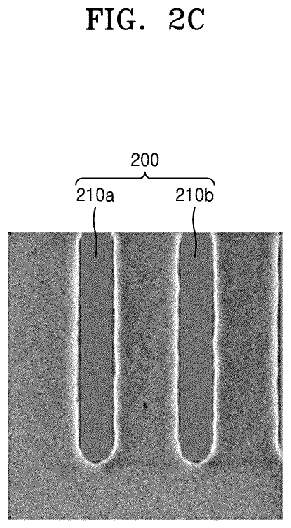

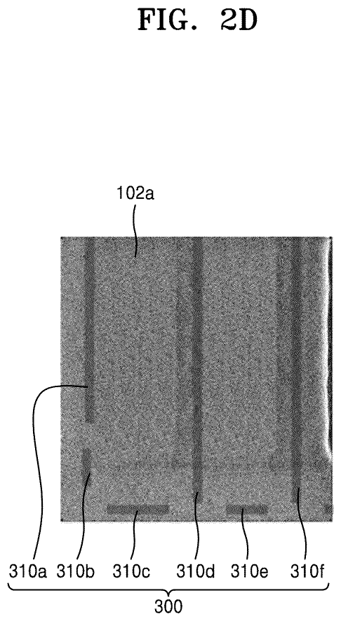

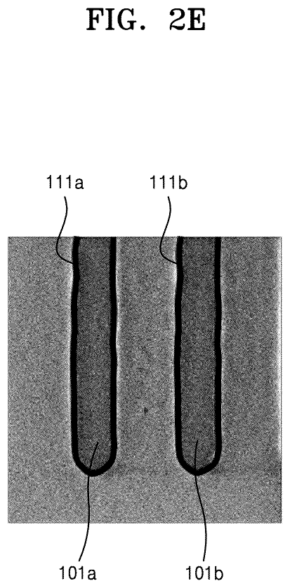

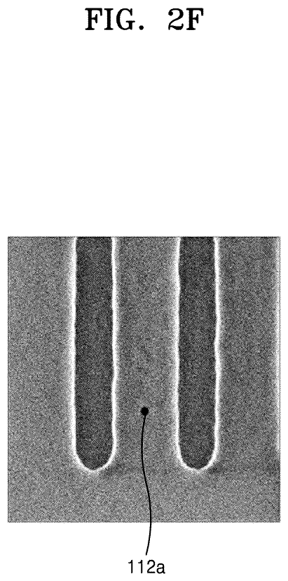

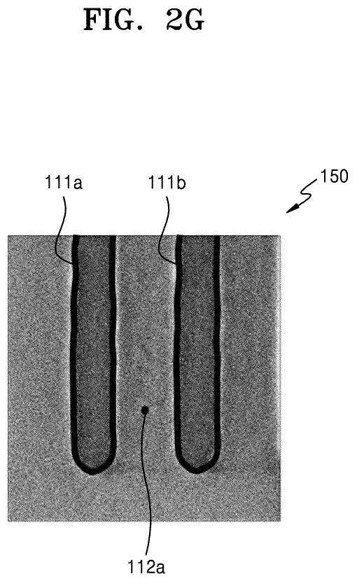

FIG. 1 is a schematic flowchart of a method of extracting sub-resolution assist feature (SRAF) contours according to an example embodiment, and FIGS. 2A to 2G are examples of scanning electron microscope (SEM) images for describing respective operations of FIG. 1.

Referring to FIGS. 1 and 2A, according to the method of extracting SRAF contours according to an example embodiment, an SEM image 100 of a wafer W may be first obtained through an SEM (operation S110). The wafer W may be a silicon bulk wafer, an epitaxial wafer, etc. An epitaxial wafer may include a crystalline material layer grown through an epitaxial process on a bulk wafer, e.g., an epitaxial layer. However, the wafer W is not limited to a bulk wafer or an epitaxial wafer. For example, the wafer W may include various types of wafers, such as a polished wafer, an annealed wafer, and a silicon-on-insulator (SOI) wafer.

The wafer W may include a plurality of semiconductor chips. The wafer W may be separated into individual semiconductor chips through a subsequent singulation process. Semiconductor chips may include identical patterns that constitute a semiconductor device. A pattern on the wafer W or a semiconductor chip may be formed through a series of semiconductor processes, such as a photolithography process and/or an etching process.

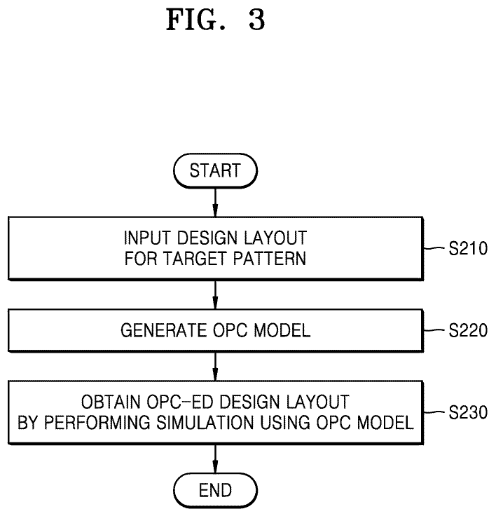

To form a pattern on a wafer, a photolithography process using a mask may generally be performed. To perform such a photolithography process, it is necessary to manufacture a mask first. A mask may be simply defined as a pattern transfer material in which a pattern shape of an opaque material is formed on a transparent base material. To manufacture a mask, after designing a layout for a demanded circuit pattern, optical proximity correction (OPC) may be performed on the layout for the demanded circuit pattern to obtain OPC-processed layout data, and the OPC-processed layout data may be delivered to a mask manufacturing team as mask tape-out (MTO) design data. Detailed descriptions of an OPC method and a mask manufacturing method will be given below in the descriptions with reference to FIGS. 3 to 6.

An OPC model may be generated to perform the OPC. The process of generating an OPC model is called OPC modeling, and, during the OPC modeling, a critical dimension (CD) of a pattern to be actually formed on a wafer may be used. Therefore, an SEM image regarding the pattern to be formed on the wafer may be obtained, and the CD for the pattern may be measured from the SEM image. Also, during the OPC modeling, an edge placement (EP) gauge including contours of the pattern may be used as well as the CD of the pattern.

For reference, as a pattern on a mask becomes finer, the optical proximity effect (OPE) due to an influence of neighboring patterns to each other may occur during an exposure process. The OPC method is a method of suppressing the occurrence of the OPE by correcting the design layout of the pattern on the mask. In other words, due to the OPE, a size and a shape of a pattern to be formed on a wafer may be changed according to a density and an arrangement of a pattern on a mask, and the OPC method may be performed to correct the changes. Although various techniques may be used to performing the OPC, correction using an OPC model may be performed in most cases.

OPC methods may be divided into two types: a rule-based OPC method and a simulation-based or model-based OPC method. The model-based OPC method may be advantageous in terms of time and cost, because only measurement results of representative patterns are used without the need to measure all of a large number of test patterns. The OPC method according to an example embodiment may be, for example, a model-based OPC method, that is, a correction method using an OPC model. Here, the OPC model may be a simulation model that may output a shape of an exposure result on a wafer for a design layout of a particular pattern on a mask and may output a simulation image by reflecting the mask, an optical phenomenon, and a resist characteristic.

The OPC method may not only include a method of changing a layout of a pattern, but also include a method of adding sub-lithographic features called as serifs on corners of a pattern or a method of adding SRAFs such as scattering bars. Here, serifs are generally rectangular features located on respective corners of a pattern and may be used to “sharpen” the corners of the pattern or to compensate for distortion factors caused by an intersection of patterns. An SRAF is an auxiliary feature introduced to resolve an OPC deviation problem caused by a difference between densities of patterns and is a feature that may be formed in a size smaller than a resolution of an exposure equipment and may not be transferred to a resist layer.

SRAFs are generally not transferred onto a wafer, but may be transferred onto a wafer due to an OPC error in an OPC model. Referring to FIG. 2A, the SEM image 100 may include main feature regions 101a and 101b and an SRAF printing region 102. AN SRAF printing region refers to an image of an SRAF pattern transferred onto a wafer.

According to the disclosure, the performance of an OPC model may be improved by identifying an SRAF printing region in an SEM image, extracting SRAF printing contours, and generating or correcting an OPC model by using information regarding extracted SRAF printing contours.

Referring to FIGS. 1 and 2A to 2D, the main feature regions 101a and 101b and the SRAF printing region 102 may be identified in the SEM image 100 (operation S120).

In detail, referring to FIGS. 2A-2B, the main feature regions 101a and 101b and the SRAF printing region 102 may be confirmed in the SEM image 100. To identify the main feature regions 101a and 101b and the SRAF printing region 102 in the SEM image 100, a first OPC layer 200 including main feature patterns 210a and 210b and a second OPC layer 300 including SRAF patterns 310a, 310b, 310c, 310d, 310e, and 310f may be compared with the SEM image 100. In other words, since the main feature regions 101a and 101b of the SEM image 100 originate from the first OPC layer 200 including the main feature patterns 210a and 210b and the SRAF printing region 102 originates from the second OPC layer 300 including the SRAF patterns 310a, 310b, 310c, 310d, 310e, and 310f, the main feature regions 101a and 101b may be identified on the SEM image 100 by comparing the first OPC layer 200 with the SEM image 100 and the SRAF printing region 102 may be identified on the SEM image 100 by comparing the second OPC layer 300 with the SEM image 100.

After comparing the SEM image 100 with the first OPC layer 200 and the second OPC layer 300, as shown in FIG. 2C, the main feature regions 101a and 101b may be set by excluding regions corresponding to the SRAF patterns 310a, 310b, 310c, 310d, 310e, and 310f of the second OPC layer 300 from the SEM image 100. In other words, regions of the SEM image 100 corresponding to the SRAF patterns 310a, 310b, 310c, 310d, 310e, and 310f may be excluded, and regions of the SEM image 100 corresponding to the main feature patterns 210a and 210b of the first OPC layer 200 may be set as the main feature regions 101a and 101b, respectively.

Also, as shown in FIG. 2D, regions of the SEM image 100 corresponding to the main feature patterns 210a and 210b of the first OPC layer 200 may be excluded, thereby setting an SRAF pattern region 102a. In other words, in the SEM image 100, by excluding regions corresponding to the main feature patterns 210a and 210b of the first OPC layer 200, regions of the SEM image 100 corresponding to the SRAF patterns 310a, 310b, 310c, 310d, 310e, and 310f may be set as the SRAF pattern region 102a. The SRAF pattern region 102a may include the SRAF printing region 102. The SRAF pattern region 102a may be a region on the SEM image 100 corresponding to the SRAF patterns 310a, 310b, 310c, 310d, 310e, and 310f of the second OPC layer 300 and, as described above, the SRAF patterns 310a, 310b, 310c, 310d, 310e, and 310f may not be transferred onto the wafer. However, due to various errors, some of the SRAF patterns 310a, 310b, 310c, 310d, 310e, and 310f of the second OPC layer 300 may be transferred onto the wafer, and thus the SRAF printing region 102 may be expressed in the SEM image 100.

Next, as shown in FIG. 2E, main feature contours 111a and 111b may be extracted from the main feature regions 101a and 101b.

In the extraction of main feature contours, a first blending image may be generated by performing first blending on the SEM image 100 and a first background image, a second blending image may be generated by performing second blending on a second background image and the SEM image 100, and the main feature contours may be extracted through binarization of the second blending image.

The first background image may be an image regarding an OPC layer including a main feature pattern. The second background image may be generated by performing Gaussian blur on the first background image.

In detail, the first background image may be generated by imaging an OPC layer including a main feature, a rounded target, or a pseudo model contour, and the first blending image may be generated by blending the first background image and the SEM image 100.

Next, the second background image may be generated by performing Gaussian blur on the first blending image, the second blending image may be generated by blending the second background image and the SEM image 100, and main feature contours 111a and 111b may be extracted by binarizing the second blending image based on a threshold value.

As shown in FIGS. 1 and 2F, an SRAF printing contour 112a may be extracted from the SRAF printing region 102 (operation S140).

In the extraction of an SRAF contour, a first blending image may be generated by performing first blending on the SEM image 100 and a first background image, a second blending image may be generated by performing second blending on a second background image and the SEM image 100, and an SRAF contour may be extracted through binarization of the second blending image.

The first background image may be an image regarding an OPC layer including an SRAF pattern. The second background image may be generated by performing Gaussian blur on the first background image.

In detail, the first background image may be generated by imaging an OPC layer including an SRAF, and the first blending image may be generated by blending the first background image and the SEM image.

Next, the second background image may be generated by performing Gaussian blur on the first blending image, the second blending image may be generated by blending the second background image and the SEM image, and an SRAF contour may be extracted by binarizing the second blending image based on a threshold value.

Values of an alpha, a median, and a threshold from among parameters used in the second blending operation may be smaller than values of an alpha, a median, and a threshold from among parameters used in the first blending operation, respectively.

The alpha may be a parameter that represents a ratio of blending a background image to an SEM image, the median may be a parameter that removes noise from the SEM image, and the threshold may be a parameter that represents the threshold for creating an edge in an image generated after blending.

Referring to FIGS. 1 and 2G, a final SEM contour image 150 may be generated by merging the main feature contours 111a and 111b with the SRAF printing contour 112a (operation S150). The final SEM contour image 150 may include both information regarding the main feature contours 111a and 111b and information regarding the SRAF printing contour 112a.

Next, a model gauge may be generated from the final SEM contour image 150. The model gauge may be an input gauge for an OPC model and may be used as an input gauge for creating a new OPC model or as an input gauge for calibration of an existing OPC model.

The model gauge may include information regarding whether patterns in the final SEM contour image 150 correspond to an SRAF printing region and information regarding the area of the SRAF printing region. Table 1 shows an example of the model gauge.

TABLE 1

| NAME | SRAF_PRINT | SRAF_PRINT_AREA |
|---|---|---|
| PATTERN_1 | 0 | 0 |
| PATTERN_2 | 0 | 0 |
| PATTERN_3 | 1 | 35 |
| PATTERN_4 | 1 | 15 |
| PATTERN_5 | 0 | 0 |

Referring to Table 1, the model gauge may include information regarding whether each of patterns 1 to 5 (PATTERN_1 to PATTERN_5) in the final SEM contour image 150 corresponds to an SRAF printing region and information regarding the area of the SRAF printing region. The model gauge may assign an SRAF_PRINT value corresponding to a pattern among the patterns 1 to 5 to 1 when a pattern in the final SEM contour image 150 corresponds to the SRAF printing region and assign the SRAF_PRINT value corresponding to a pattern among the patterns 1 to 5 to 0 when the pattern in the final SEM contour image 150 does not correspond to the SRAF printing region. In other words, the model gauge may assign the SRAF_PRINT value corresponding to patterns 1, 2, and 5 to 0 when a pattern 1 PATTERN_1, a pattern 2 PATTERN_2, and a pattern 5 PATTERN_5 do not correspond to the SRAF printing region and assign the SRAF_PRINT value corresponding to patterns 3 and 4 to 1 when a pattern 3 PATTERN_3 and a pattern 4 PATTERN_4 correspond to the SRAF printing region.

The model gauge may assign, as the information regarding the area of the SRAF printing region, areas in the SRAF printing region to 35 and 15, the areas corresponding to the pattern 3 PATTERN_3 and the pattern 4 PATTERN_4, respectively. The information (e.g., 35 and 15 in Table 1) may be an index indicating the areas in the SRAF printing region that correspond to the patterns 3 and 4 in the final SEM contour image 150.

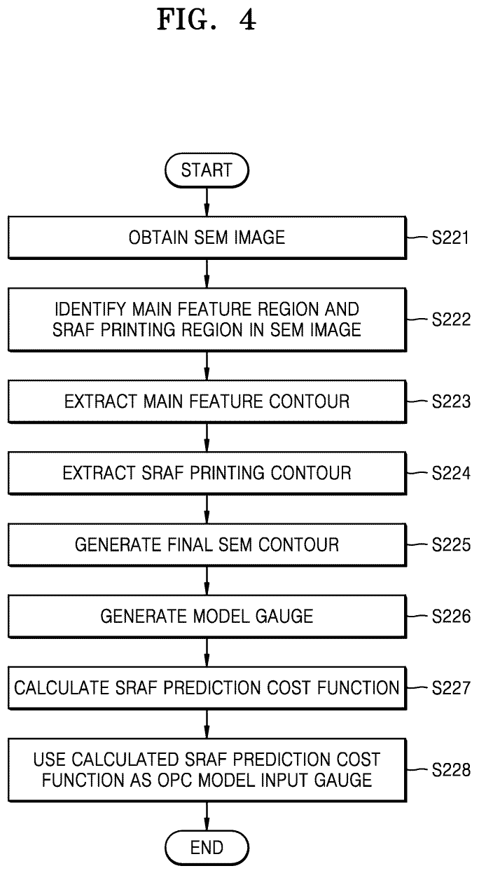

FIG. 3 is a schematic flowchart of an OPC method according to an example embodiment, and FIG. 4 is a flowchart schematically showing an operation of generating an OPC model of FIG. 3. Descriptions will be given below with reference to FIGS. 1 to 2G, and descriptions already given above with reference to FIGS. 1 to 2G will be briefly given or omitted.

The OPC method according to an example embodiment may receive a design layout for a target pattern (operation S210). Here, the target pattern may refer to a pattern to be formed on a silicon (Si) substrate such as a wafer. In other words, a pattern on a mask may be transferred to a substrate through an exposure process, thereby forming a target pattern on the substrate. Since a pattern on a mask is generally scaled down and projected onto a wafer, the pattern on the mask may have a larger size than a target pattern on a substrate.

A design layout may refer to the layout of a pattern on a mask corresponding to a target pattern. Due to the nature of an exposure process, the shape of a target pattern on a wafer may be different from the shape of a pattern on an actual mask used in the exposure process. However, the shape of the initial design layout for the pattern on the mask may be substantially identical to the shape of the target pattern on the wafer. Generally, a design layout may have the shape of an orthogonal design layout. The shape of an orthogonal design layout may refer to a shape in which edges include only straight lines. However, the shape of the design layout is not limited to the shape of an orthogonal design layout.

Afterwards, for the design layout, an OPC model that reflects an optical phenomenon during the exposure process and a characteristic of a photoresist (PR) may be generated (operation S220).

In operation of generating the OPC model, reflection of the optical phenomenon during the exposure process may include optimization of a defocus stand (DS) position and a best focus (BF) position in the exposure process. The refection of the optical phenomenon during the exposure process may further include generation of a mask image taking into account diffraction of light or an optical state of exposure equipment itself. However, the generation of an OPC model is not limited to the descriptions given above. In other words, the generation of an OPC model may include various technical features related to an optical phenomenon during an exposure process. For example, in relation to generation of an OPC model, calculation of an optical mask image, that is, a near-field image of a mask, in consideration of the effect of mask topography may precede. Rigorous simulation techniques such as rigorous coupled-wave analysis (RCWA) or finite difference time domain (FDTD) simulation may be used to calculate the near-field image of a mask, but edge filters may be commonly used for fast calculation of a near-field image of a mask.

In reflecting the characteristic (or nature) of the PR, an operation of generating an OPC model may include optimization of a threshold value of the PR. Here, the threshold value of the PR refers to a threshold value at which a chemical change occurs during an exposure process. For example, the threshold value may be given as an intensity of exposure light. Also, generation of an OPC model may include selecting and combining appropriate kernel functions from among several register kernel functions. Here, kernel functions are basis functions used in non-parametric estimation technique and may be used to simulate a characteristic of a resist image in an OPC model. In the OPC method according to an example embodiment, different combinations of kernel functions may be applied to respective regions within a target pattern or a design layout corresponding to the target pattern, in the process of generating a second OPC model.

As shown in FIG. 4, operation S220 of generating an OPC model according to an example embodiment may include operation S221 of obtaining an SEM image to operation S228 of using an SRAF prediction cost function as an OPC model input gauge, and operations S221 to S228 may be sequentially performed. However, this is only an example and the disclosure is not limited thereto. One or more of operations S221 to S228 may be executed in a different order or omitted, or one or more other operations may be added. Operation S221 of obtaining an SEM image to operation S226 of generating a model gauge may be identical to operation S110 of obtaining an SEM image to operation S160 of generating a model gauge of the method of extracting an SRAF contour of FIG. 1 described above. Thus, repetitive descriptions will be omitted.

After a model gauge is generated, an SRAF prediction cost function COST FUNCTIONₛₚ may be calculated (operation S227).

The SRAF prediction cost function COST FUNCTIONₛₚ may be calculated using Equation (1) below.

$$Equation ( 1 )$$

$$COST {FUNCTION}_{sp} {\sum }_{i} {{W}_{i} ( SRAF sim . {contour}_{i} ( m ) - SRAF {contour}_{i} )}^{2}$$

Wi may denote a weight, SRAF sim.contour may denote an SRAF contour obtained by an OPC simulation, and SRAF contour may denote the SRAF printing contour. The SRAF sim.contour may be based on position coordinates of an outline of an SRAF pattern obtained by an OPC simulation. The SRAF contour may be based on position coordinates of an outline of an SRAF printing region.

A calculated SRAF prediction cost function COST FUNCTIONₛₚ may be used as an input gauge for the OPC model (operation S228). The SRAF prediction cost function COST FUNCTIONₛₚ may be a square value of a difference between the SRAF contour according to the OPC simulation and the SRAF printing contour on an imaginary line lying in a normal direction at a certain position of the SRAF printing contour. The smaller a value of the SRAF prediction cost function COST FUNCTIONₛₚ is, the lower an error rate of an OPC model may be. Therefore, according to the disclosure, the SRAF prediction cost function COST FUNCTIONₛₚ may be calculated and an OPC model may be modelled such that the SRAF prediction cost function COST FUNCTIONₛₚ is equal to or less than a certain value, thereby lowering the error rate for an SRAF of the OPC model.

According to an embodiment, the disclosure may further include an operation of calculating an SRAF printing prediction score for an OPC model and an operation of optimizing the OPC model such that the SRAF printing prediction score is within a certain range.

The SRAF printing prediction score may include a first score Sp and a second score Snp.

The first score Sp may be calculated according to Equation (2) below.

$$Equation ( 2 )$$

$${S}_{p} = \frac{AREA [ ( Moldel sim . Contour ) and ( SRAF priniting contour ) ]}{{AREA ( SRAF priniting contour ( m ) )}^{2}} \times 100 ( \% )$$

The second score Snp may be calculated according to Equation (3) below.

$$Equation ( 3 )$$

$${S}_{np} = \frac{AREA [ ( Moldel sim . Contour ) xor ( SRAF priniting contour ) by under over {T}_{clean} ]}{{AREA ( SRAF priniting contour ( m ) )}^{2}} \times 100 ( \% )$$

Here, Model sim.Contour denotes an SRAF contour calculated according to a simulation of the OPC model, and SRAF printing contour denotes an SRAF printing contour extracted from the SEM image.

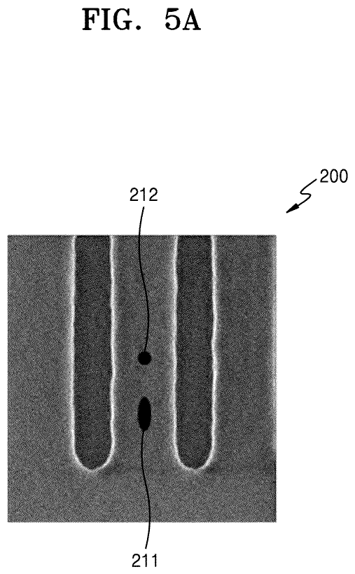

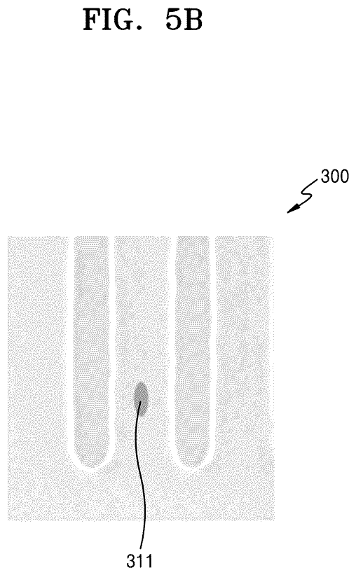

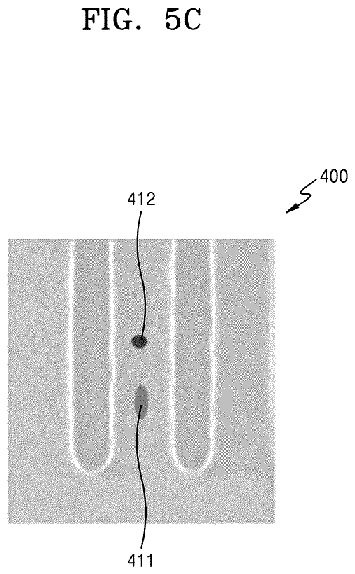

FIG. 5A shows an image 200 having an SRAF printing region, FIG. 5B shows an image 300 having an SRAF printing region calculated by simulation of an OPC model, and FIG. 5C shows an image 400 having an SRAF printing predicted region and an SRAF printing unpredicted region.

The image 200 of FIG. 5A may be an image of a wafer and shows two SRAF printing regions 211 and 212. The image 300 of FIG. 5B may be an image obtained by a simulation of an OPC model and represents one SRAF printing region 311. The SRAF printing region 311 of FIG. 5B may correspond to the SRAF printing region 211 of FIG. 5A. However, the image 300 of FIG. 5B generated by a simulation of an OPC model may not include a region corresponding to the SRAF printing region 212 of FIG. 5A. In other words, the OPC model was unable to predict the SRAF printing region 212. The image 400 of FIG. 5C shows an SRAF printing predicted region 411 and an SRAF printing unpredicted region 412.

The first score Sp of the SRAF printing prediction score may be a ratio of an area of a region in which an SRAF contour calculated by a simulation of an OPC model and an SRAF printing contour overlap each other with respect to an area of the SRAF printing contour. The higher the first score Sp, the more precise the SRAF printing prediction of the OPC model.

The second score Snp may be a ratio of an area corresponding to an exclusive OR of an SRAF contour, calculated by a simulation of an OPC model and an SRAF printing contour with respect to an area of the SRAF printing contour. The lower the second score Snp, the more precise the SRAF printing prediction of the OPC model.

According to the disclosure, an OPC model with improved SRAF printing prediction precision may be generated by calculating the first score Sp and the second score Snp with respect to an OPC model and calibrating the OPC model, such that the first score Sp is equal to or greater than a certain value and the second score Snp is less than or equal to a certain value.

After the OPC model is generated, a simulation using the OPC model may be performed to obtain an OPC design layout (operation S230).

By performing a simulation using the OPC model, a simulation image corresponding to a target pattern, which is an OPC result, may be generated. A contour may be extracted from the simulation image. When a similarity between the contour and a target pattern is at a maximum, a design layout corresponding to the contour may be obtained as an OPC-ed design layout. In other words, the OPC method may correspond to a process of making a contour extracted through a simulation using an OPC model as similar as possible to a shape of the target pattern. A simulation process and a comparison process using an OPC model may not be performed once, but may be repeated, e.g., dozens to hundreds of times.

In detail, when a design layout is initially input, the design layout may be divided into a plurality of segments and input to an OPC model. For reference, a segment may also be referred to as a fragment and may refer to a straight line corresponding to an edge of a design layout or data regarding the straight line. Thereafter, a simulation image may be generated through a simulation using the OPC model, and a contour corresponding to a target pattern may be extracted from the simulation image. Next, an edge placement error (EPE) may be calculated by comparing the target pattern with the contour extracted from the simulation image. Here, the EPE refers to a difference between edges of the target pattern and a simulated contour, and the EPE may be calculated at each of set evaluation points. Thereafter, positions of segments may be changed, and based on the changed positions, a contour may be extracted and EPEs may be calculated gain through a simulation using the OPC model. This process may be repeated until an EPE falls within a set range or until a number of repetitions reaches a set number. After repetition of the process ends, a final design layout may correspond to the OPC-ed design layout.

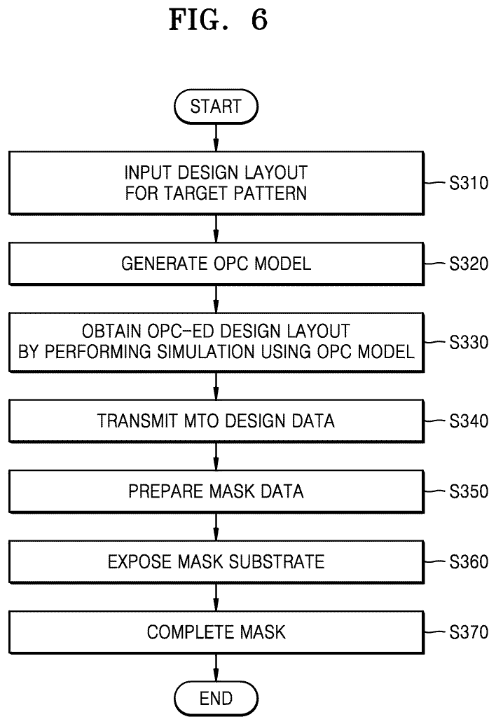

FIG. 6 is a schematic flowchart of operations of a mask manufacturing method including an OPC method, according to an example embodiment. Descriptions will be given below with reference to FIGS. 1 to 4, and descriptions already given above with reference to FIGS. 1 to 5C will be briefly given or omitted.

According to the mask manufacturing method including the OPC method according to an example embodiment (hereinafter simply referred to as a ‘mask manufacturing method’), operation S310 of receiving a design layout for a target pattern to operation S330 of obtaining an OPC-ed design layout may be performed sequentially. Operation S310 of receiving a design layout for a target pattern to operation S330 of obtaining an OPC-ed design layout may be identical to operation S210 of receiving a design layout for a target pattern to operation S230 of obtaining an OPC-ed design layout of the OPC method of FIGS. 3 and 4. Thus, repetitive descriptions will be omitted.

Thereafter, MTO design data may be delivered to a mask manufacturing team (operation S340). In general, MTO may refer to a process of providing data regarding a final design layout obtained through an OPC method to request manufacturing of a mask. Therefore, in the mask manufacturing method according to an example embodiment, the MTO design data may refer to an OPC-ed design layout obtained through an OPC method or data regarding the OPC-ed design layout. Such MTO design data may have a graphic data format used in electronic design automation (EDA) software, etc. For example, the MTO design data may have a data format such as Graphic Data System II (GDS2), Open Artwork System Interchange Standard (OASIS), etc.

Thereafter, mask data preparation (MDP) may be performed (operation S350). The MDP may include, for example, i) format conversion, which may be called fracturing, ii) augmentation including, for example, barcodes for mechanical reading, a standard mask pattern for inspection, a job deck, etc., and iii) automatic and manual verification. Here, the job deck may refer to generation of a text file regarding a series of instructions such as arrangement information of multiple mask files, a standard dose, and a speed or a method for exposure.

The format conversion, e.g., fracturing, may refer to a process of dividing MTO design data into respective regions and converting the MTO design data to a format for electron beam exposure equipment. The fracturing may include data manipulation, such as scaling, sizing of data, rotating of data, reflecting a pattern, and inverting colors. During a conversion process through fracturing, data regarding a large number of systematic errors that may occur somewhere during transmission from design data to an image on a wafer may be corrected.

The process of correction of data regarding systematic errors may be called mask process correction (MPC) and may include, for example, a task for adjusting a line width called CD adjustment and a task for improving pattern placement precision. Therefore, the fracturing may contribute to improving the quality of a final mask and may also be a process that is performed in advance for mask process correction. Here, the systematic errors may be caused by distortions occurring in an exposure process, a mask development and etching process, and a wafer imaging process.

The MDP may include the MPC. As described above, the MPC may refer to a process of correcting an error that may occur during an exposure process, that is, a systematic error. Here, the exposure process may be an overall concept that includes electron beam writing, development, etching, baking, etc. Also, data processing may be performed prior to the exposure process. The data processing may be a preprocessing process regarding mask data and may include grammar check for mask data, exposure time prediction, etc.

After mask data is prepared, a mask substrate may be exposed based on the mask data (operation S360). Here, the exposure may mean, for example, electron beam writing. Here, the electron beam writing may be performed, for example, through a gray writing method using a multi-beam mask writer (MBMW). Also, the electron beam writing may also be performed using variable shape beam (VSB) exposure equipment.

After the MDP, a process of converting the mask data into pixel data may be performed before an exposure process. Pixel data may be data directly used for actual exposure and may include data regarding a shape to be exposed and data regarding the dose assigned to each shape. Here, the data regarding a shape may be bit-map data obtained by converting shape data, which is vector data, through rasterization or the like.

After the exposure process, a series of processes may be performed to complete a mask (operation S370). The series of processes may include, for example, development, etching, and cleaning. Also, a series of processes for manufacturing a mask may include a metrology process, a defect inspection process, or a defect repair process. Furthermore, the series of processes for manufacturing a mask may include a pellicle application process. Here, the pellicle application process may refer to a process of attaching pellicles to a mask surface to protect a mask from subsequent contamination during delivery and during a useful life of the mask when it is confirmed that there are no contaminant particles or chemical stains through final cleaning and inspection.

While the disclosure has been particularly shown and described with reference to example embodiments thereof, it will be understood that various changes in form and details may be made therein without departing from the spirit and scope of the following claims and their equivalents.

What is claimed is:

1. A method of extracting a sub-resolution assist feature (SRAF) contour, the method comprising:
obtaining a scanning electron microscope (SEM) image of a wafer through an SEM;
identifying a main feature region and an SRAF printing region in the SEM image;
extracting, from the SEM image, a main feature contour, which is an outermost line of the main feature region;
extracting, from the SEM image, an SRAF printing contour, which is an outermost line of the SRAF printing region; and
generating a final SEM contour image by merging the main feature contour with the SRAF printing contour.

2. The method of claim 1, wherein the identifying the main feature region and the SRAF printing region comprises:
comparing a first optical proximity correction (OPC) layer comprising a main feature pattern and a second OPC layer comprising an SRAF pattern, with the SEM image; and
setting, as the main feature region, a region in the SEM image excluding the SRAF pattern of the second OPC layer and setting, as the SRAF printing region, a region in the SEM image excluding the main feature pattern of the first OPC layer.

3. The method of claim 1, wherein the extracting the main feature contour comprises:
generating a first blending image by performing a first blending operation on the SEM image and a first background image;
generating a second blending image by performing a second blending operation on the SEM image and a second background image generated based on the first blending image; and
extracting the main feature contour by binarizing the second blending image, and
wherein the first background image comprises an image for an optical proximity correction (OPC) layer comprising a main feature pattern.

4. The method of claim 1, wherein the extracting the SRAF printing contour comprises:
generating a first blending image by performing a first blending operation on the SEM image and a first background image;
generating a second blending image by performing a second blending operation on the SEM image and a second background image generated based on the first blending image; and
extracting the SRAF printing contour by binarizing the second blending image, and
wherein the first background image comprises an image for an optical proximity correction (OPC) layer comprising an SRAF pattern.

5. The method of claim 4, wherein values of an alpha, a median, and a threshold from among parameters used in the second blending operation are smaller than values of an alpha, a median, and a threshold from among parameters used in the first blending operation, respectively.

6. The method of claim 1, further comprising generating a model gauge from the final SEM contour image,
wherein the model gauge comprises information regarding whether at least one pattern in the final SEM contour image corresponds to the SRAF printing region and information regarding an area of the SRAF printing region corresponding to the at least one pattern.

7. An optical proximity correction (OPC) method comprising:
receiving a design layout for a target pattern;
generating an OPC model for the design layout; and
obtaining an OPC-ed design layout by performing a simulation using the OPC model,
wherein the generating the OPC model comprises:
obtaining a scanning electron microscope (SEM) image of a wafer through an SEM;
identifying a main feature region and a sub-resolution assist feature (SRAF) printing region in the SEM image;
extracting, from the SEM image, a main feature contour, which is an outermost line of the main feature region;
extracting, from the SEM image, an SRAF printing contour, which is an outermost line of the SRAF printing region;
generating a final SEM contour image by merging the main feature contour with the SRAF printing contour;
generating a model gauge from the final SEM contour image;
obtaining an SRAF prediction cost function using the model gauge; and
using the SRAF prediction cost function as an input gauge for the OPC model.

8. The OPC method of claim 7, wherein the SRAF prediction cost function is obtained using Equation (1) below:
$$Equation ( 1 )$$
$$COST {FUNCTION}_{sp} {\sum }_{i} {{W}_{i} ( SRAF sim . {contou r}_{i} ( m ) - SRAF {contour}_{i} )}^{2} ,$$
where Wi denotes a weight, SRAF sim.contour denotes an SRAF contour obtained by the simulation using the OPC model, and SRAF contour denotes the SRAF printing contour.

9. The OPC method of claim 7, wherein the generating the OPC model comprises:
obtaining an SRAF printing prediction score for the OPC model; and
optimizing the OPC model such that the SRAF printing prediction score is within a certain range.

10. The OPC method of claim 9, wherein the SRAF printing prediction score comprises a first score Sp and a second score Snp,
wherein the first score Sp is obtained according to Equation (2) below:
$$Equation ( 2 )$$
$${S}_{p} = \frac{AREA [ ( Moldel sim . Contour ) and ( SRAF priniting contour ) ]}{{AREA ( SRAF priniting contour ( m ) )}^{2}} \times 100 ( \% ) ,$$
and
wherein the second score Snp is obtained according to Equation (3) below:
$${S}_{np} = \frac{AREA [ ( Moldel sim . Contour ) xor ( SRAF priniting contour ) by under over {T}_{clean} ]}{{AREA ( SRAF priniting contour ( m ) )}^{2}} \times 100 ( \% ) ,$$
where Model sim.Contour denotes an SRAF contour obtained by the simulation using the OPC model, and SRAF printing contour is the SRAF printing contour extracted from the SEM image.

11. The OPC method of claim 7, wherein the identifying the main feature region and the SRAF printing region in the SEM image comprises:
comparing a first OPC layer comprising a main feature pattern and a second OPC layer comprising an SRAF pattern, with the SEM image; and
setting, as the main feature region, a region in the SEM image excluding the SRAF pattern of the second OPC layer and setting, as the SRAF printing region, a region in the SEM image excluding the main feature pattern of the first OPC layer.

12. The OPC method of claim 7, wherein the extracting the main feature contour comprises:
generating a first blending image by performing a first blending operation on the SEM image and a first background image;
generating a second blending image by performing a second blending operation on the SEM image and a second background image generated based on the first blending image; and
extracting the main feature contour by binarizing the second blending image, and
wherein the first background image comprises an image for an OPC layer comprising a main feature pattern.

13. The OPC method of claim 7, wherein the extracting the SRAF printing contour comprises:
generating a first blending image by performing a first blending operation on the SEM image and a first background image;
generating a second blending image by performing a second blending operation on the SEM image and a second background image generated based on the first blending image; and
extracting the SRAF printing contour by binarizing the second blending image, and
wherein the first background image comprises an image for an OPC layer comprising an SRAF pattern.

14. The OPC method of claim 13, wherein values of an alpha, a median, and a threshold from among parameters used in the second blending operation are smaller than values of an alpha, a median, and a threshold from among parameters used in the first blending operation, respectively.

15. The OPC method of claim 7, wherein the model gauge comprises information regarding whether at least one pattern in the final SEM contour image corresponds to the SRAF printing region and information regarding an area of the SRAF printing region corresponding to the at least one pattern.

16. A method of manufacturing a mask, the method comprising:
receiving a design layout for a target pattern;
generating an optical proximity correction (OPC) model for the design layout;
obtaining an OPC-ed design layout by performing a simulation using the OPC model;
transmitting data regarding the OPC-ed design layout as mask tape-out (MTO) design data;
preparing mask data based on the MTO design data; and
performing exposure on a mask substrate based on the mask data,
wherein the generating the OPC model comprises:
obtaining a scanning electron microscope (SEM) image of a wafer through an SEM;
identifying a main feature region and a sub-resolution assist feature (SRAF) printing region in the SEM image;
extracting, from the SEM image, a main feature contour, which is an outermost line of the main feature region;
extracting, from the SEM image, an SRAF printing contour, which is an outermost line of the SRAF printing region;
generating a final SEM contour image by merging the main feature contour with the SRAF printing contour;
generating a model gauge from the final SEM contour image;
obtaining an SRAF prediction cost function using the model gauge; and
using the SRAF prediction cost function as an input gauge for the OPC model, and
wherein the model gauge comprises information regarding whether at least one pattern in the final SEM contour image corresponds to the SRAF printing region and information regarding an area of the SRAF printing region corresponding to the at least one pattern.

17. The method of claim 16, wherein the SRAF prediction cost function is obtained using Equation (1) below:
$$Equation ( 1 )$$
$$COST {FUNCTION}_{sp} {\sum }_{i} {{W}_{i} ( SRAF sim . {contour}_{i} ( m ) - SRAF {contour}_{i} )}^{2} ,$$
where Wi denotes a weight, SRAF sim.contour denotes an SRAF contour obtained by simulation using the OPC model, and SRAF contour denotes the SRAF printing contour.

18. The method of claim 16, wherein the generating the OPC model comprises:
obtaining an SRAF printing prediction score for the OPC model; and
optimizing the OPC model such that the SRAF printing prediction score is within a certain range.

19. The method of claim 18, wherein the SRAF printing prediction score comprises a first score Sp and a second score Snp,
wherein the first score Sp is obtained according to Equation (2) below:
$$Equation ( 2 )$$
$${S}_{p} = \frac{AREA [ ( Moldel sim . Contour ) and ( SRAF priniting contour ) ]}{{AREA ( SRAF priniting contour ( m ) )}^{2}} \times 100 ( \% ) ,$$
and
wherein the second score Snp is obtained according to Equation (3) below:
$$Equation ( 3 )$$
$${S}_{np} = \frac{AREA [ ( Moldel sim . Contour ) xor ( SRAF priniting contour ) by under over {T}_{clean} ]}{{AREA ( SRAF priniting contour ( m ) )}^{2}} \times 100 ( \% ) ,$$
where Model sim.Contour denotes an SRAF contour obtained by the simulation using the OPC model, and SRAF printing contour is an SRAF printing contour extracted from the SEM image.

20. The method of claim 16, wherein the identifying the main feature region and the SRAF printing region in the SEM image comprises:
comparing a first OPC layer comprising a main feature pattern and a second OPC layer comprising an SRAF pattern, with the SEM image; and
setting, as the main feature region, a region in the SEM image excluding the SRAF pattern of the second OPC layer and setting, as the SRAF printing region, a region in the SEM image excluding the main feature pattern of the first OPC layer.
